(19) United States
(12) Patent Application Publication
(10) Pub. No.: US 2024/0266786 A1
(43) Pub. Date: Aug. 8, 2024

(54) SHIELDED TERMINAL

(71) Applicant: SUMITOMO WIRING SYSTEMS, LTD., Mie (JP)

(72) Inventors: Ai HIRANO, Mie (JP); Takeyuki SUZUKI, Mie (JP)

(21) Appl. No.: 18/426,948

(22) Filed: Jan. 30, 2024

(30) Foreign Application Priority Data
Feb. 6, 2023 (JP) 2023-015959

(51) Int. Cl. H01R 13/6585

(52) U.S. Cl. CPC H01R 13/6585

(57) ABSTRACT

A shielded terminal 20 includes a first outer conductor 24 having a cylindrical main body 25, and a second outer conductor 34 having a recess 37 into which the first outer conductor 24 is fitted. When the direction in which the first outer conductor 24 fits into the recess 37 is frontward, the first outer conductor 24 includes a locking portion 27 provided on an outer peripheral surface of the main body portion 25 and a protruding piece 29 extending frontward from a front end of the main body 25. The locking portion 27 and a front end portion 29M of the protruding piece 29 are in contact with the inner surface 39 of the recess 37.

### CROSS-REFERENCE TO RELATED APPLICATIONS

This application is based on and claims priority from Japanese Patent Application No. 2023-015959, filed on Feb. 6, 2023, with the Japan Patent Office, the disclosure of which is incorporated herein in its entirety by reference.

### TECHNICAL FIELD

The present disclosure relates to a shielded terminal.

### BACKGROUND

For example, JP 2020-061340 A, JP 2021-018948 A, and WO 2016/138982 describe shielded terminals that include an inner conductor, a dielectric material, and an outer conductor. The outer conductor of the shielded terminals described in JP 2020-061340 A, JP 2021-018948 A, and WO 2016/138982 is constituted by connecting a first outer conductor and a second outer conductor. The first outer conductor has a cylindrical shape and is held by fitting into a recess provided in the second outer conductor. As a structure for maintaining the first outer conductor and the second outer conductor in a connected state, for example, JP 2020-061340 A discloses that a plurality of protrusions provided on the outer peripheral surface of the first outer conductor are brought into areal contact with the inner peripheral surface of the recess of the second outer conductor.

### SUMMARY

In the shielded terminal as described above, there has been a desire to ensure stability of the connected state between the first outer conductor and the second outer conductor.

In view of this, an object of the present disclosure is to provide a shielded terminal that can ensure stability of the connected state between the first outer conductor and the second outer conductor.

The shielded terminal of the present disclosure includes: a first outer conductor having a cylindrical main body portion; and a second outer conductor having a recess into which the first outer conductor is to be fitted, in which when a front side of a direction in which the first outer conductor is fitted into the recess is frontward, the first outer conductor includes a locking portion provided on an outer peripheral surface of the main body portion, and a protruding piece extending frontward from a front end of the main body portion, and the locking portion and a front end portion of the protruding piece are in contact with an inner surface of the recess.

According to the present disclosure, it is possible to provide a shielded terminal that can ensure stability of the connected state between the first outer conductor and the second outer conductor.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a cross-sectional view showing a shield connector according to a first embodiment.

FIG. 2 is a front view showing a first outer conductor.

FIG. 3 is a plan view showing the first outer conductor.

FIG. 4 is a side view showing the first outer conductor.

FIG. 5 is a rear view showing a second outer conductor.

FIG. 6 is a cross-sectional view showing a shielded terminal, and is a cross-sectional view corresponding to a cross-section taken at position A-A in FIG. 1.

FIG. 7 is a cross-sectional view showing the shielded terminal, and is a cross-sectional view corresponding to a cross section taken at position B-B in FIG. 6.

FIG. 8 is a cross-sectional view showing the shielded terminal, and is a cross-sectional view corresponding to a cross-section taken at position C-C in FIG. 6.

### DETAILED DESCRIPTION

In the following detailed description, reference is made to the accompanying drawings, which form a part hereof. The illustrative embodiments described in the detailed description, drawings, and claims are not meant to be limiting. Other embodiments may be utilized, and other changes may be made, without departing from the spirit or scope of the subject matter presented here.

### Description of Embodiments of Present Disclosure

First, embodiments of the present disclosure will be listed and described.

(1) The shielded terminal of the present disclosure includes: a first outer conductor having a cylindrical main body portion; and a second outer conductor having a recess into which the first outer conductor is to be fitted, in which when a direction in which the first outer conductor is fitted into the recess is frontward, the first outer conductor includes a locking portion provided on an outer peripheral surface of the main body portion, and a protruding piece extending frontward from a front end of the main body portion, and the locking portion and a front end portion of the protruding piece are in contact with an inner surface of the recess. According to such a configuration, in the first outer conductor, not only the locking portion provided on the outer peripheral surface of the main body, but also the front end portion of the protruding piece come into contact with the inner surface of the recess, and therefore stability of the connected state between the first outer conductor and the second outer conductor can be ensured.

(2) In the shielded terminal described in (1) above, it is preferable that the second outer conductor has a closing surface configured to close a front side of the recess, and the front end portion of the protruding piece is in contact with the closing surface. According to such a configuration, the amount by which the first outer conductor is pushed into the recess of the second outer conductor can be easily made constant, and therefore an insufficient pushing amount can be prevented.” This can prevent an insufficient maintaining force for maintaining the connected state between the first outer conductor and the second outer conductor.

(3) In the shielded terminal described in (1) or (2) above, it is preferable that the first outer conductor includes, in addition to the locking portion, a plurality of contact portions configured to come into contact with the inner surface of the recess. According to this configuration, it is possible to improve the shielding performance by increasing the number of electrical connection locations between the first outer conductor and the second outer conductor.

(4) In the shielded terminal described in (3) above, it is preferable that the plurality of contact portions are provided on the outer peripheral surface of the main body portion, and the plurality of contact portions and the locking portion are arranged on the same cross section intersecting a central axis of the main body portion. According to such a configuration, the shielding performance can be further improved.

(5) In the shielded terminal described in any one of (1) to (4) above, it is preferable that the protruding piece has a shape that is curved toward an outer periphery as a front end is approached, and the second outer conductor has a contact surface configured to come into contact with an intermediate portion of the protruding piece. According to such a configuration, the protruding piece is not likely to be displaced in a direction away from the inner surface of the recess, and therefore the stability of the connected state between the first outer conductor and the second outer conductor can be improved.

(6) In the shielded terminal described in any one of (1) to (5) above, it is preferable that a pair of the protruding pieces are provided on both sides in a radial direction of the main body portion. According to such a configuration, the pair of protruding pieces come into contact with the inner surface of the recess in a well-balanced manner, and therefore the stability of the connected state between the first outer conductor and the second outer conductor can be improved.

(7) In the shielded terminal described in any one of (1) to (6) above, it is preferable that the second outer conductor is a die-cast product, and the first outer conductor is a press-molded product. According to such a configuration, elasticity can be easily imparted to the protruding piece of the first outer conductor, and the rigidity of the recess of the second outer conductor can be increased, and therefore stability of the connected state between the first outer conductor and the second outer conductor can be increased.

### Details of Embodiments of Present Disclosure

Specific examples of the shielded terminal of the present disclosure will be described below with reference to the drawings. Note that the present invention is not limited to these examples, but is indicated by the scope of the claims, and is intended to include all modifications within the meaning and scope equivalent to the scope of the claims.

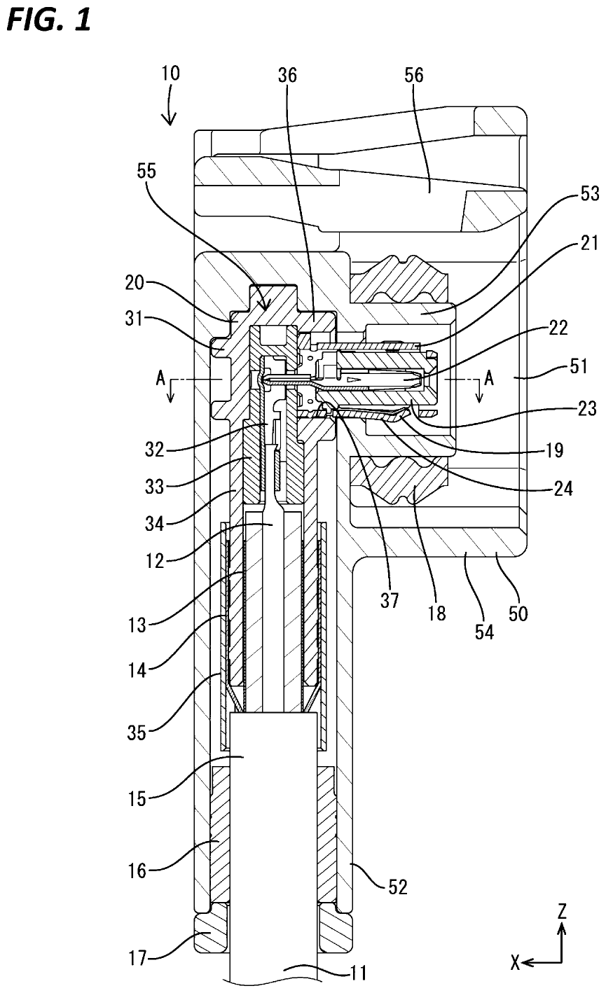

A shielded terminal 20 is included in a shield connector 10, as shown in FIG. 1. The shield connector 10 is attached to a terminal portion of a cable 11. The cable 11 has a core wire 12, an insulator 13, a shield member 14, and a sheath 15. The core wire 12 and the shield member 14 are electrically conductive. The shield member 14 is, for example, a braided wire. The insulator 13 and the sheath 15 are made of resin and have insulative properties.

The shield connector 10 is an L-shaped connector that is bent into an L-shape. The shield connector 10 includes the shielded terminal 20, a housing 50, a rubber stopper 16, a cover 17, and a rubber ring 18. The shield connector 10 is a waterproof connector. The shielded terminal 20 includes a first outer conductor 24 and a second outer conductor 34. The first outer conductor 24 has a cylindrical main body portion 25. The first outer conductor 24 fits into a recess 37 of the second outer conductor 34.

Hereinafter, in each constituent member, the direction in which the first outer conductor 24 fits into the recess 37 of the second outer conductor 34 is described as frontward, the opposite side (removal direction) is described as rearward, the side from which the cable 11 is pulled out from the shield connector 10 is described as downward, and the opposite side is described as upward. In each figure, the X axis is parallel to the direction in which the first outer conductor 24 and the second outer conductor 34 fit together. The positive direction of the X axis indicates frontward, and the negative direction of the X axis indicates rearward. The Y axis is a direction orthogonal to the X axis. The positive direction of the Y axis indicates leftward, and the negative direction of the Y axis indicates rightward. The Z axis is parallel to the direction in which the cable 11 extends. The positive direction of the Z axis indicates upward, and the negative direction of the Z axis indicates downward. “Parallel” includes a substantially parallel state in addition to a strictly parallel state.

The housing 50 is made of an insulating material such as resin. The housing 50 has a connector connection portion 51 and a cable connection portion 52, as shown in FIG. 1. The connector connection portion 51 has an inner cylinder portion 53 and an outer cylinder portion 54. Both the inner cylinder portion 53 and the outer cylinder portion 54 are open in the direction of fitting with a partner connector. The axes of the inner cylinder portion 53 and the outer cylinder portion 54 are parallel to the X axis.

The cable connection portion 52 has a cylindrical shape and is open downward. The axis of the cable connection portion 52 is parallel to the Z axis.

The axis of the connector connection portion 51 and the axis of the cable connection portion 52 are orthogonal to each other. The internal space of the connector connection portion 51 and the internal space of the cable connection portion 52 are continuous with each other at a bent portion 55.

The housing 50 has a lock piece 56 for locking the shield connector 10 and the partner connector in a fitted state. The lock piece 56 is provided on the upper surface of the connector connection portion 51.

The rubber stopper 16 is fitted into the lower end portion of the cable connection portion 52. The rubber stopper 16 is in areal contact with the cable 11 and the cable connection portion 52. The rubber stopper 16 seals the location where the cable 11 is pulled out.

The cover 17 is made of an insulating material such as resin. The cover 17 is attached to the lower end of the cable connection portion 52. The cover 17 prevents the rubber stopper 16 from falling off.

The rubber ring 18 is attached to the outer peripheral surface of the inner cylinder portion 53. The rubber ring 18 is in areal contact with a partner connector. The rubber ring 18 seals the location of fitting with the partner connector.

As shown in FIG. 1, the shielded terminal 20 is an L-shaped terminal that is bent into an L shape. The shielded terminal 20 is accommodated in the bent portion 55 of the housing 50. The shielded terminal 20 includes a first terminal 21 and a second terminal 31. The first terminal 21 and the second terminal 31 are connected to each other at the bent portion 55 of the housing 50. The first terminal 21 is connected to a terminal fitting of the partner connector. The front end portion of the first terminal 21 fits into the recess 37. The rear end portion of the first terminal 21 protrudes rearward from the recess 37. The rear end portion of the first terminal 21 is surrounded by the inner cylinder portion 53 of the connector connection portion 51.

The first terminal 21 includes a first inner conductor 22, a first dielectric material 23, and the first outer conductor 24. The first inner conductor 22 is electrically conductive and is formed by bending a metal plate, for example. The first inner conductor 22 has a shape that is elongated in the X-axis direction. The front end portion of the first inner conductor 22 is connected to the second inner conductor 32. The rear end portion of the first inner conductor 22 is connected to an inner conductor of a partner connector.

The first dielectric material 23 has insulative properties and is interposed between the first inner conductor 22 and the first outer conductor 24. The first inner conductor 22 is accommodated inside the first dielectric material 23. The first dielectric material 23 is accommodated inside the first outer conductor 24. As a result, the first inner conductor 22 is held at the center of the first outer conductor 24.

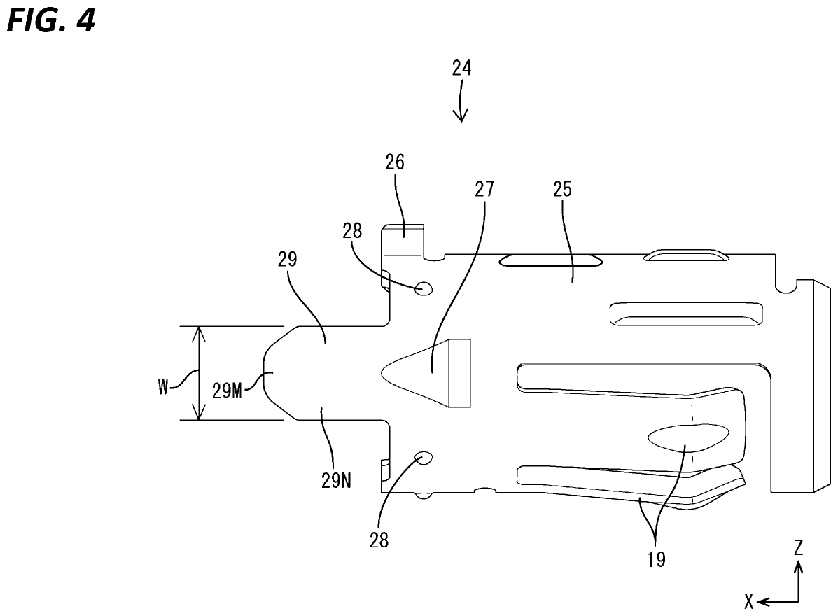

The first outer conductor 24 is a press-molded product obtained by press-molding an electrically-conductive metal plate. The first outer conductor 24 has elastic contact pieces 19 that come into contact with an outer conductor of the partner connector (see FIG. 4).

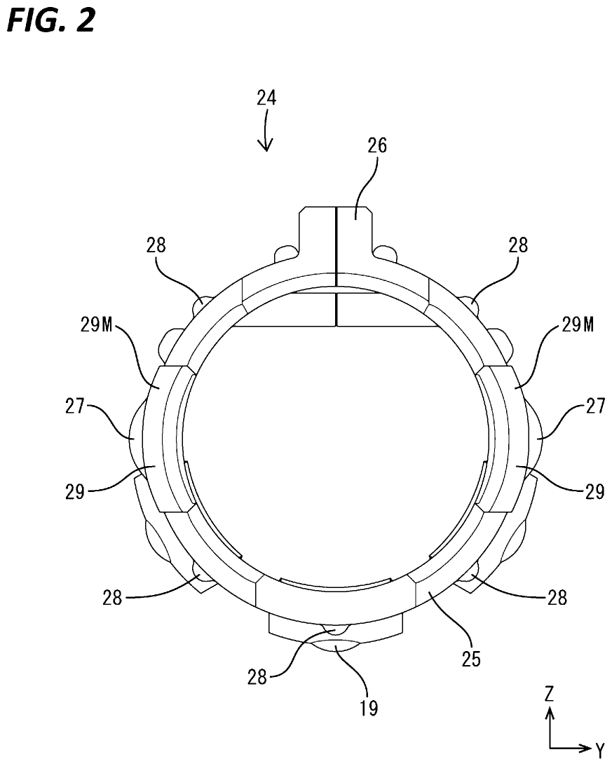

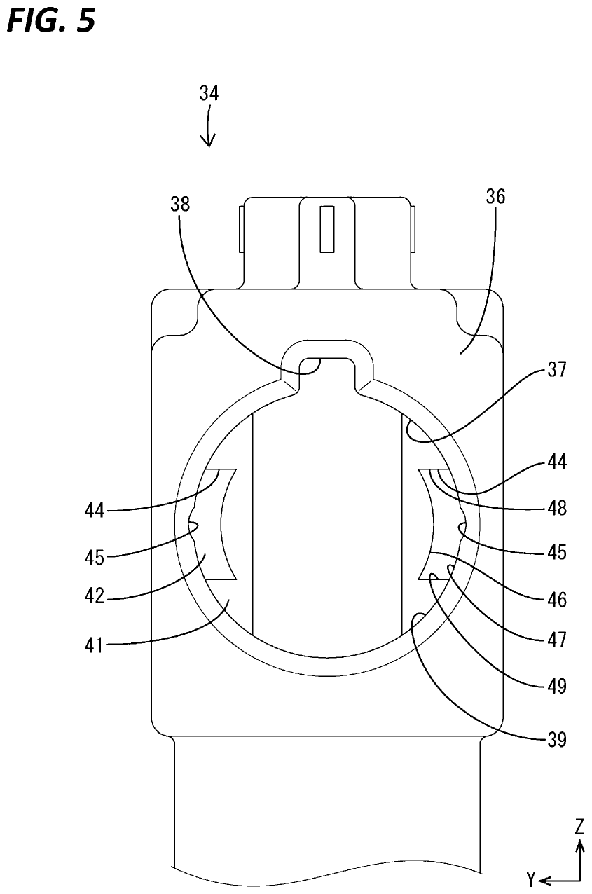

The main body portion 25 of the first outer conductor 24 has a cylindrical shape, as shown in FIG. 2. The main body portion 25 has a protrusion 26 that protrudes toward the outer periphery. The protrusion 26 is formed by bending parts of the metal plate constituting the main body portion 25 toward the outer circumference and abutting them against each other in the peripheral direction. The protrusion 26 is provided at the front end portion of the main body portion 25 (see FIG. 4). The protrusion 26 is accommodated in a notch 38 provided in the recess 37 of the second outer conductor 34 (see FIG. 5). The protrusion 26 prevents relative rotation between the first terminal 21 and the second terminal 31 when accommodated in the notch 38.

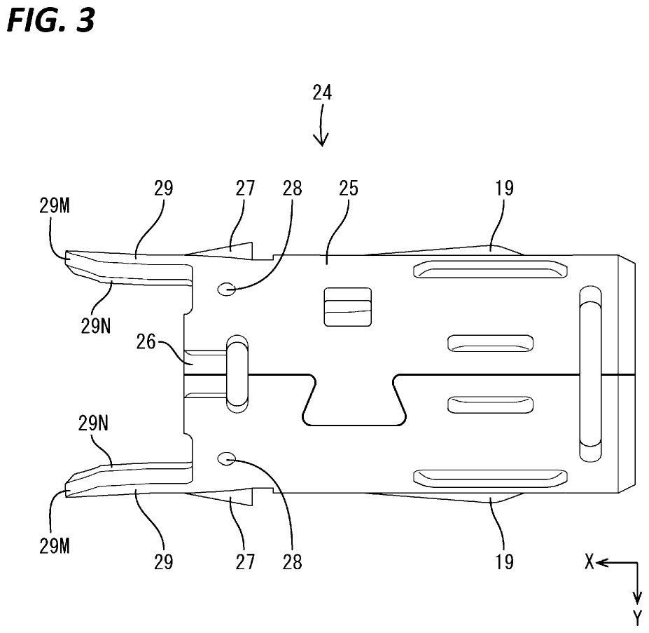

As shown in FIG. 3, the first outer conductor 24 includes locking portions 27, contact portions 28, and protruding pieces 29. The locking portions 27 are provided on the outer peripheral surface of the main body portion 25. The locking portions 27 are provided at the front end portion of the main body portion 25. A pair of locking portions 27 are provided in the radial direction of the main body portion 25. The pair of locking portions 27 are provided symmetrically with respect to the central axis of the main body portion 25. The locking portions 27 are formed by punching. The protruding height of the locking portions 27 gradually increases from the front end to the rear end in the state before the first terminal 21 and the second terminal 31 are connected. The state before the first terminal 21 and the second terminal 31 are connected is referred to as a state before connection. In the state after the first terminal 21 and the second terminal 31 are connected, the locking portions 27 come into contact with an inner peripheral surface 39 of the recess 37 of the second outer conductor 34, collapse slightly, and come into areal contact with the inner peripheral surface 39 of the recess 37. The state after the first terminal 21 and the second terminal 31 are connected is referred to as a connected state. As shown in FIG. 4, in the state before connection, the locking portions 27 have a triangular shape with an apex at the front end in a side view seen from the left-right direction.

As shown in FIG. 2, the contact portions 28 are provided on the outer peripheral surface of the main body portion 25 separately from the locking portions 27. Five contact portions 28 are provided on the outer peripheral surface of the main body portion 25. One of the five contact portions 28 is provided at a position 180 degrees opposite to the protrusion 26 with the central axis of the main body portion 25 therebetween. The other four contact portions 28 are provided such that one is provided above and one is provided below each of the locking portions 27. The contact portions 28 and the locking portions 27 are arranged in a well-balanced manner around the entire circumference of the main body portion 25. The contact portions 28 and the locking portions 27 are symmetrical with respect to the center in the left-right direction.

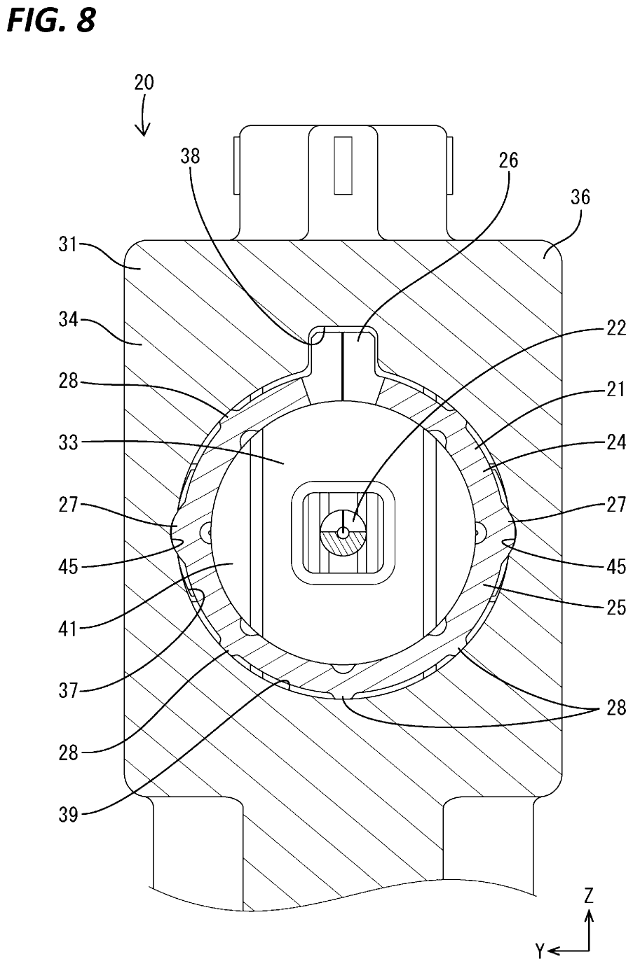

As shown in FIGS. 3 and 4, the contact portions 28 are smaller than the locking portions 27 and have a round shape in a view from the outer peripheral side of the main body portion 25. The five contact portions 28 and the two locking portions 27 are arranged on the same cross section orthogonal to the central axis of the main body portion 25, as shown in FIG. 8. The contact portions 28 are in contact with the inner peripheral surface 39 of the recess 37 in the connected state. The locking portions 27 and the contact portions 28 together serve as electrical connection locations between the first outer conductor 24 and the second outer conductor 34.

As shown in FIG. 2, the pair of protruding pieces 29 are provided on both sides in the radial direction of the main body portion 25. Each protruding piece 29 has an arc shape that follows the shape of the main body portion 25.

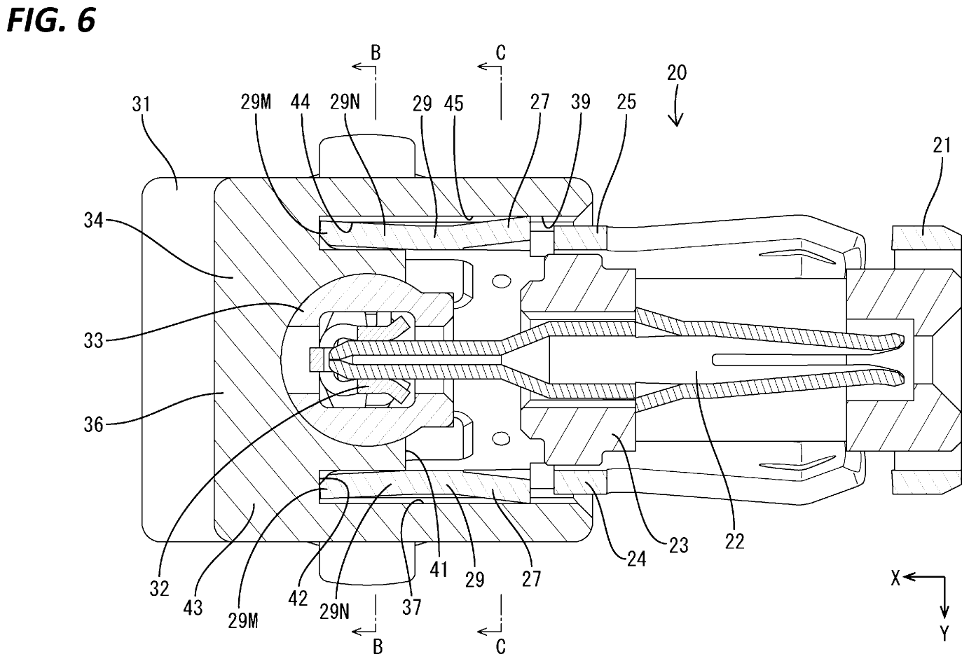

Each protruding piece 29 extends frontward from the front end of the main body 25, as shown in FIG. 3. Each protruding piece 29 has a shape that is curved toward the outer periphery toward the front end. As shown in FIG. 6, the front ends of the protruding pieces 29 are located slightly frontward relative to the front end of the first inner conductor 22 in the first terminal 21. Intermediate portions 29N in the extension direction of the protruding pieces 29 are located radially inward relative to front end portions 29M in the extension direction of the protruding pieces 29. The front end portions 29M of the pair of protruding pieces 29 are inclined so as to open outward in the radial direction.

As shown in FIG. 4, the pair of protruding pieces 29 are provided at positions aligned with the locking portions 27 in the peripheral direction. A dimension W in the peripheral direction of each protruding piece 29 is larger than the maximum dimension in the peripheral direction of the locking portions 27 in the state before connection. At the front end portions 29M of the protruding pieces 29, the dimension W in the peripheral direction of the protruding pieces 29 gradually decreases toward the front ends.

The second terminal 31 has a second inner conductor 32, a second dielectric material 33, a second outer conductor 34, and a sleeve 35, as shown in FIG. 1. The second inner conductor 32 is electrically conductive and is formed by bending a metal plate, for example. The second inner conductor 32 has a shape that is elongated in the Z-axis direction. The lower end portion of the second inner conductor 32 is crimped to the core wire 12 of the cable 11. The upper end portion of the second inner conductor 32 is electrically connected to the front end portion of the first inner conductor 22. The first inner conductor 22 and the second inner conductor 32 are arranged to be orthogonal to each other.

The second dielectric material 33 has insulative properties and is interposed between the second inner conductor 32 and the second outer conductor 34. The second inner conductor 32 is accommodated inside the second dielectric material 33. The second dielectric material 33 is accommodated inside the second outer conductor 34. As a result, the second inner conductor 32 is held at the center of the second outer conductor 34.

The second terminal 31 is connected to the terminal portion of the cable 11. The second outer conductor 34 is a die-cast product. As shown in FIG. 1, the second outer conductor 34 has a shape that is elongated in the Z-axis direction. The lower end portion of the second outer conductor 34 is electrically connected to the shield member 14 of the cable 11. Specifically, the shield member 14 is placed over the outer peripheral surface of the second outer conductor 34 and crimped with the sleeve 35. The sleeve 35 is crimped in the range from the shield member 14 to the insulator 13.

The upper end portion of the second outer conductor 34 is a terminal fitting portion 36. The terminal fitting portion 36 fits with the first terminal 21. The recess 37 is provided in the terminal fitting portion 36. The recess 37 is open to the rear. The terminal fitting portion 36 has no opening other than the recess 37. As a result, the shielding performance of the shield connector 10 is favorable.

As shown in FIG. 5, the terminal fitting portion 36 has a quadrangular shape. The recess 37 is formed at the center of the terminal fitting portion 36 in a view from the rear. The recess 37 has the notch 38. The protrusion 26 of the first terminal 21 fits into the notch 38. The inner surface of the recess 37 has the inner peripheral surface 39, a first closing surface 41, and second closing surfaces 42. The inner peripheral surface 39 has a cylindrical shape along the outer peripheral surface of the main body portion 25 of the first outer conductor 24. The first closing surface 41 and the second closing surfaces 42 close the front side of the recess 37. The first closing surface 41 and the second closing surfaces 42 are orthogonal to the X axis, as shown in FIG. 6. The first closing surface 41 is located at the center in the front-rear direction of the terminal fitting portion 36. A portion of the terminal fitting portion 36 on the front side relative to the first closing surface 41 is a thick portion 43. The second closing surfaces 42 are the inner surfaces of accommodating grooves 44, which will be described later.

The recess 37 has the accommodating grooves 44 for the protruding pieces 29, as shown in FIG. 6. The accommodating grooves 44 are provided in the thick portion 43. The accommodating grooves 44 accommodate the front end portions 29M of the protruding pieces 29 in the connected state. The accommodating grooves 44 extend frontward from the first closing surface 41. As shown in FIG. 5, a pair of accommodating grooves 44 are provided on the left and right sides. The pair of accommodating grooves 44 are symmetrical with respect to the center in the left-right direction of the terminal fitting portion 36. Each accommodating groove 44 has an arc shape along the inner peripheral surface 39 of the recess 37 in a view from the rear side.

As shown in FIG. 5, the recess 37 has guide grooves 45 that guide the protruding pieces 29 to the accommodating grooves 44. The guide grooves 45 are recessed outward in the inner peripheral surface 39 of the recess 37 in a view from the rear side. The guide grooves 45 have an arc shape. The guide grooves 45 extend continuously and linearly from the rear end of the recess 37 to the second closing surfaces 42.

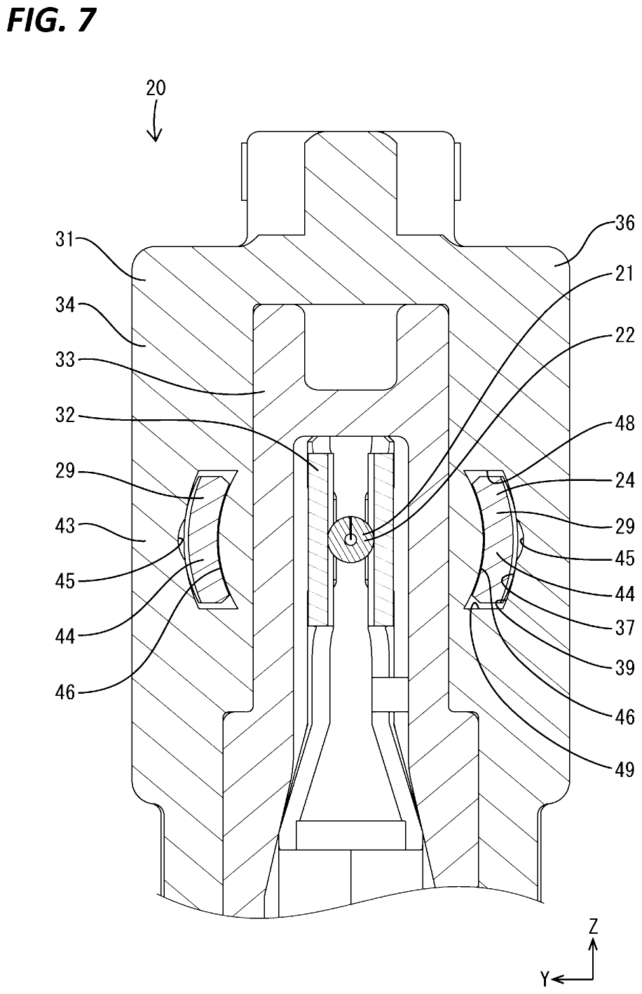

As shown in FIG. 7, each accommodating groove 44 is entirely surrounded by the inner peripheral surface 39 of the recess 37, a groove inner surface 46, a groove upper surface 48, and a groove lower surface 49. The groove inner surface 46 has a curved shape parallel to the inner peripheral surface 39 of the recess 37. The groove upper surface 48 and the groove lower surface 49 are parallel to each other. The groove inner surface 46, the groove upper surface 48, and the groove lower surface 49 are formed in the thick portion 43. The groove inner surface 46 constitutes a contact surface with which the intermediate portion 29N of the protruding piece 29 comes into contact.

Next, an example of a procedure for assembling the shield connector 10 will be described. First, the second terminal 31 is crimped onto the terminal end of the cable 11 that has already been passed through the rubber stopper 16.

Next, the second terminal 31 is inserted into the housing 50. The second terminal 31 is inserted into the housing 50 from the lower end of the cable connection portion 52 with the terminal fitting portion 36 facing upward.

Next, the first terminal 21 is connected to the second terminal 31. The first terminal 21 fits into the recess 37 of the second terminal 31 with the protruding pieces 29 facing frontward. At this time, the pair of protruding pieces 29 protect the front end portion of the first inner conductor 22. The first terminal 21 is inserted into the recess 37 such that the pair of protruding pieces 29 are aligned with the guide grooves 45 of the recess 37. The first terminal 21 advances along the guide grooves 45. The locking portions 27 of the first outer conductor 24 come into contact with the inner peripheral surface 39 of the recess 37 and gradually collapse. Then, the front end portions 29M of the protruding pieces 29 abut against the second closing surfaces 42. As a result, the forward movement of the first terminal 21 is stopped, and the first terminal 21 and the second terminal 31 enter a normal connected state.

In the connected state, the front end portions 29M of the protruding pieces 29 are in contact with the inner peripheral surface 39 of the recess 37. Each protruding piece 29 is preferably in contact with the inner peripheral surface 39 in an elastically deformed state. In the connected state, the intermediate portions 29N in the extension direction of the protruding pieces 29 are in contact with the contact surface. This restricts displacement of the protruding pieces 29 toward the inner peripheral side. In the connected state, the contact portions 28 and the locking portions 27 are in contact with the inner peripheral surface 39 of the recess 37, as shown in FIG. 8. In this way, the shield connector 10 is assembled.

Next, the operation and effects of the embodiment configured as described above will be described. The shielded terminal 20 includes the first outer conductor 24 and the second outer conductor 34. The first outer conductor 24 has the cylindrical main body portion 25. The second outer conductor 34 has the recess 37 into which the first outer conductor 24 is fitted. The first outer conductor 24 has the locking portions 27 provided on the outer peripheral surface of the main body 25 and the protruding pieces 29 extending frontward from the front end of the main body 25. The locking portions 27 and the front end portions 29M of the protruding pieces 29 are in contact with the inner peripheral surface 39 of the recess 37. According to this configuration, in the first outer conductor 24, not only the locking portions 27 provided on the outer peripheral surface of the main body portion 25, but also the front end portions 29M of the protruding pieces 29 come into contact with the inner peripheral surface 39 of the recess 37, and therefore, the stability of the connected state between the first outer conductor 24 and the second outer conductor 34 can be ensured.

The second outer conductor 34 has the second closing surfaces 42 that close the front side of the recess 37. The front end portions 29M of the protruding pieces 29 are in contact with the second closing surfaces 42. According to this configuration, the amount by which the first outer conductor 24 is pushed into the recess 37 of the second outer conductor 34 can be easily made constant, and therefore an insufficient pushing amount can be prevented. As a result, it is possible to prevent an insufficient holding force for maintaining the connected state between the first outer conductor 24 and the second outer conductor 34.

The first outer conductor 24 includes, in addition to the locking portions 27, the plurality of contact portions 28 that come into contact with the inner surface of the recess 37. According to this configuration, the shielding performance can be improved by increasing the number of electrical connection locations between the first outer conductor 24 and the second outer conductor 34.

The plurality of contact portions 28 are provided on the outer peripheral surface of the main body portion 25. The plurality of contact portions 28 and the locking portions 27 are arranged on the same cross section orthogonal to the central axis of the main body portion 25. According to this configuration, the shielding performance can be further improved.

The protruding pieces 29 each have a shape that is curved toward the outer periphery toward the front end. The second outer conductor 34 has the groove inner surfaces 46 that come into contact with the intermediate portions 29N of the protruding pieces 29. According to this configuration, the protruding pieces 29 are less likely to be displaced in a direction away from the inner peripheral surface 39 of the recess 37, and therefore the stability of the connected state between the first outer conductor 24 and the second outer conductor 34 can be improved.

A pair of protruding pieces 29 are provided on both sides in the radial direction of the main body portion 25. According to this configuration, the pair of protruding pieces 29 come into contact with the inner surface of the recess 37 in a well-balanced manner, and therefore the stability of the connected state between the first outer conductor 24 and the second outer conductor 34 can be improved.

The second outer conductor 34 is a die-cast product, and the first outer conductor 24 is a press-molded product. According to this configuration, elasticity can be easily imparted to the protruding pieces 29 of the first outer conductor 24, and the rigidity of the recess 37 of the second outer conductor 34 can be increased, and therefore the stability of the connected state between the first outer conductor 24 and the second outer conductor 34 can be improved.

### Other Embodiments of the Present Disclosure

The embodiments disclosed herein are to be considered illustrative in all respects and not restrictive.

In the case of the above embodiment, the intermediate portions 29N of the protruding pieces 29 are in contact with the groove inner surfaces 46, but in other embodiments, the intermediate portions of the protruding pieces may not be in contact with the groove inner surfaces. In this case, the second outer conductor does not need to have an accommodating groove.

In the case of the above embodiment, the intermediate portions 29N in the extension direction of the protruding pieces 29 are located radially inward relative to the front end portions 29M in the extension direction of the protruding pieces 29, but in other embodiments, the protruding pieces may be curved in the opposite direction. Specifically, the intermediate portions in the extension direction of the protruding pieces may be located radially inward relative to the front end portions in the extension direction of the protruding pieces. In this case, the front end portions of the protruding pieces may be brought into contact with the groove inner surfaces.

In the above embodiment, the contact portions 28 and the locking portions 27 are arranged on the same cross section, but in other embodiments, the contact portions and the locking portions may be shifted in the front-rear direction.

In the above embodiment, the second outer conductor 34 is a die-cast product, but in other embodiments, the second outer conductor may be a cut product.

From the foregoing, it will be appreciated that various exemplary embodiments of the present disclosure have been described herein for purposes of illustration, and that various modifications may be made without departing from the scope and spirit of the present disclosure. Accordingly, the various exemplary embodiments disclosed herein are not intended to be limiting, with the true scope and spirit being indicated by the following claims.

What is claimed is:

1. A shielded terminal, comprising:
a first outer conductor having a cylindrical main body portion; and
a second outer conductor having a recess into which the first outer conductor is to be fitted,
wherein when a direction in which the first outer conductor is fitted into the recess is frontward,
the first outer conductor includes a locking portion provided on an outer peripheral surface of the main body portion, and a protruding piece extending frontward from a front end of the main body portion, and
the locking portion and a front end portion of the protruding piece are in contact with an inner surface of the recess.

2. The shielded terminal according to claim 1,
wherein the second outer conductor has a closing surface configured to close a front side of the recess, and
the front end portion of the protruding piece is in contact with the closing surface.

3. The shielded terminal according to claim 1,
wherein the first outer conductor includes, in addition to the locking portion, a plurality of contact portions configured to come into contact with the inner surface of the recess.

4. The shielded terminal according to claim 3,
wherein the plurality of contact portions are provided on the outer peripheral surface of the main body portion, and
the plurality of contact portions and the locking portion are arranged on the same cross section intersecting a central axis of the main body portion.

5. The shielded terminal according to claim 1,
the protruding piece has a shape that is curved toward an outer periphery as a front end is approached, and
the second outer conductor has a contact surface configured to come into contact with an intermediate portion of the protruding piece.

6. The shielded terminal according to claim 1,
wherein a pair of the protruding pieces are provided on both sides in a radial direction of the main body portion.

7. The shielded terminal according to claim 1,
wherein the second outer conductor is a die-cast product, and the first outer conductor is a press-molded product.
